(19) United States
(12) Patent Application Publication
(10) Pub. No.: US 2026/0250164 A1
(43) Pub. Date: Aug. 27, 2026

(54) METHOD OF CARBON CAPTURE AND RECYCLING TETRAMETHYL AMMONIUM CARBONATE-CONTAINING SOLUTION

(71) Applicant: UNITED MICROELECTRONICS CORP., Hsin-Chu City (TW)

(72) Inventors: Kun-Ju Li, Tainan City (TW); Chun-Tsen Lu, Tainan City (TW); Yi-Wei Chen, Taichung City (TW); Chih-Chieh Tsai, Kaohsiung City (TW); Po-Chun Chen, Tainan City (TW); Tung-Chang Kuo, Chiayi City (TW); Kai-Lou Huang, New Taipei City (TW); Ju-Te Chen, Tainan City (TW); Chiao-Yi Teng, Taichung City (TW); Hsin-Yu Yen, Taichung City (TW)

(73) Assignee: UNITED MICROELECTRONICS CORP., Hsin-Chu City (TW)

(21) Appl. No.: 19/093,190

(22) Filed: Mar. 27, 2025

(30) Foreign Application Priority Data
Feb. 27, 2025 (TW) 114107328

(51) Int. Cl. C02F 1/66; C02F 1/04; C02F 1/70; C02F 101/16

(52) U.S. Cl. CPC C02F 1/66; C02F 1/04; C02F 1/70; C02F 2101/16; C02F 2201/002; C02F 2209/06

(57) ABSTRACT

A method of carbon capture and recycling tetramethyl ammonium carbonate-containing solution includes providing a recycling apparatus. The recycling apparatus includes a reactor. The reactor includes a cover, a side wall and a bottom. A fluid supply tube is suspended in the reactor close to the cover. Numerous spray nozzles are connected to the fluid supply tube. Numerous nozzles are arranged on the side wall. The method of recycling tetramethyl ammonium carbonate-containing solution by using carbon dioxide is performed by using the recycling apparatus. The method incudes supplying tetramethyl ammonium carbonate-containing solution into the fluid supply tube and spraying out from the spraying nozzles. Meanwhile, the carbon dioxide-containing gas is turned on to spray the carbon dioxide-containing gas from the nozzles. The PH value of the tetramethyl ammonium carbonate-containing solution is reduced after adjusted by the carbon dioxide-containing gas.

### BACKGROUND OF THE INVENTION

### 1. Field of the Invention

The present invention relates to a method of carbon capture and recycling tetramethyl ammonium carbonate-containing solution, particularly relates with using industrial waste gas—carbon dioxide—generated during semiconductor manufacturing processes to recycle the tetramethyl ammonium carbonate-containing solution.

### 2. Description of the Prior Art

Tetramethyl ammonium hydroxide (TMAH) is a strong alkaline aqueous solution and is the most widely used chemical in the semiconductor development process. With the rapid improvement of advanced manufacturing processes, the demand for TMAH continues to rise.

In the photolithography process, the photoresist is evenly distributed on substrates such as wafers, glass, and metals. Through the exposure and development steps, circuit patterns are transferred onto the photoresist-coated substrates. The photoresist can be classified into positive and negative photoresists based on changes in solubility after exposure and development. The main developer for positive photoresist is TMAH. The waste water discarded after development is the development waste solution, which mainly includes water, TMAH, and the photoresist dissolved in it.

Since TMAH waste solution is a strong alkaline solution and highly toxic to aquatic life, improper disposal can cause significant environmental impact. Therefore, improving the recovery rate of TMAH and reducing the recycling cost are key objectives in the semiconductor manufacturing industry.

### SUMMARY OF THE INVENTION

In light of this, the present invention utilizes carbon dioxide-containing industrial waste gas to reduce the PH value of TMAH waste solution. This process not only recycles TMAH but also reduces carbon dioxide emissions.

According to a preferred embodiment of the present invention, a method of carbon capture and recycling tetramethyl ammonium carbonate-containing solution includes providing a recycling apparatus. The recycling apparatus includes a reactor including a cover, a side wall and a bottom. A fluid inlet and a fluid recycle inlet are arranged on the side wall. A fluid supply tube is suspended in the reactor close to the cover, and the fluid supply tube is connected to the fluid inlet and the fluid recycle inlet. Numerous spray nozzles are disposed on the fluid supply tube. An inlet of each of the spray nozzles is connected to the fluid supply tube, and an outlet of each of the spray nozzles faces the bottom of the reactor. Numerous nozzles are arranged on the side wall. Some of the nozzles are arranged at a same distance from the bottom, while others of the nozzles are arranged at different distances from the bottom, the some of the nozzles which are at the same distance from the bottom are evenly distributed on the side wall to surround the side wall. A process of recycling tetramethyl ammonium carbonate-containing solution is performed by using the recycling apparatus, wherein the process includes supplying a tetramethyl ammonium carbonate-containing solution into the fluid supply tube and spraying the tetramethyl ammonium carbonate-containing solution out from the spraying nozzles. Later, a carbon dioxide-containing gas is turned on to spray the carbon dioxide-containing gas from each of the plurality of nozzles. A PH value of the tetramethyl ammonium carbonate-containing solution is reduced after adjusted by the carbon dioxide-containing gas.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a sectional view of a recycling apparatus according to a preferred embodiment of the present invention.

FIG. 2 depicts a partial schematic view of a reactor according to a preferred embodiment of the present invention.

FIG. 3 depicts a top view of a reactor according to a first preferred embodiment of the present invention.

FIG. 4 depicts a top view of a reactor according to a second preferred embodiment of the present invention.

FIG. 5 is a flowchart of a method of carbon capture and recycling tetramethyl ammonium carbonate-containing solution according to the present invention.

### DETAILED DESCRIPTION

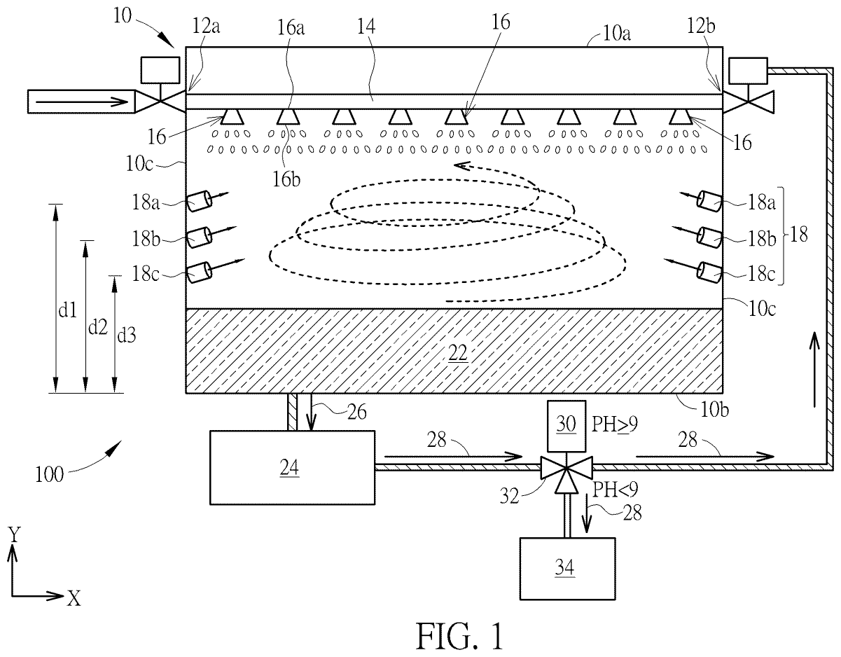

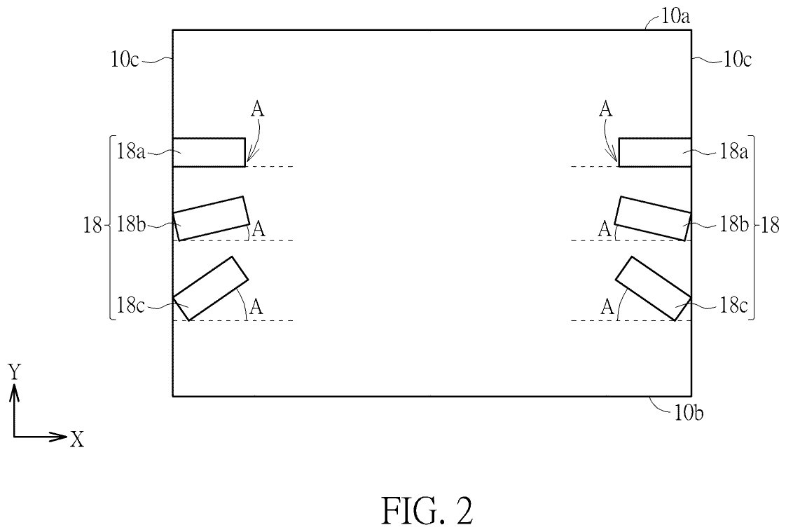

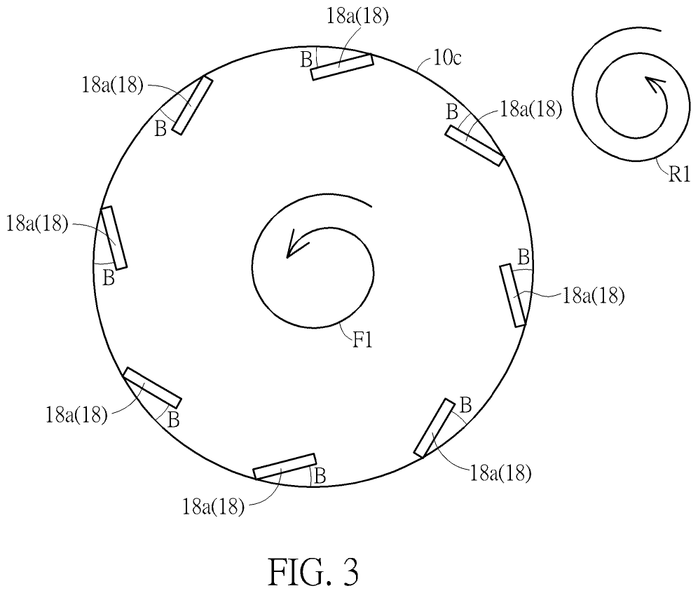

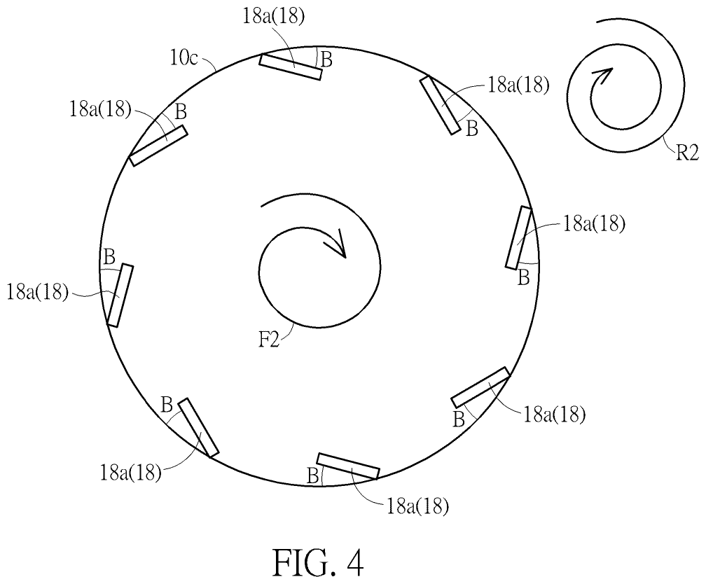

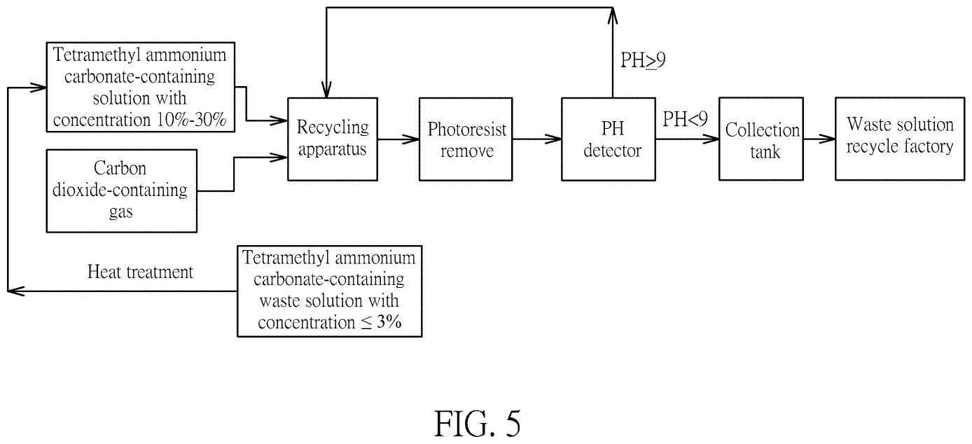

FIG. 1 depicts a sectional view of a recycling apparatus according to a preferred embodiment of the present invention. FIG. 2 depicts a partial schematic view of a reactor according to a preferred embodiment of the present invention. FIG. 3 depicts a top view of a reactor according to a first preferred embodiment of the present invention. FIG. 4 depicts a top view of a reactor according to a second preferred embodiment of the present invention. FIG. 5 is a flowchart of a method of carbon capture and recycling tetramethyl ammonium carbonate-containing solution according to the present invention.

The method of the present invention utilizes carbon dioxide-containing industrial waste gas to recycle the development waste solution generated from the developer used in the photolithography process, thus achieving both carbon capture and the recycling of development waste solution. The aforementioned development waste solution contains a low concentration of tetramethyl ammonium carbonate (chemical formula: N(CH₃)₄⁺CO₃²⁻) dissolved in water. The tetramethyl ammonium carbonate-containing waste solution (development waste solution) is formed by dissolving tetramethyl ammonium hydroxide (chemical formula: N(CH₃)₄⁺OH⁻) in water and reacting tetramethyl ammonium hydroxide with carbon dioxide from the air. In addition to tetramethyl ammonium carbonate, the tetramethyl ammonium carbonate-containing waste solution also contains residual photoresist. According to a preferred embodiment of the present invention, the concentration of the low-concentration tetramethyl ammonium carbonate-containing waste solution is approximately 2-3% (weight/weight percentage).

As shown in FIG. 5, the tetramethyl ammonium carbonate-containing waste solution is heated to evaporate the water in the waste solution, thereby increasing the concentration of the tetramethyl ammonium carbonate-containing waste solution to form a tetramethyl ammonium carbonate-containing solution with a concentration of 10-30% (weight/weight percentage). At this point, the PH value of the tetramethyl ammonium carbonate-containing solution is approximately 11-12. The tetramethyl ammonium carbonate-containing waste solution can be heated by any method. For example, the heat generated by a waste gas burner can be used to heat the tetramethyl ammonium carbonate-containing waste solution.

As shown in FIG. 1 and FIG. 5, the tetramethyl ammonium carbonate-containing solution and carbon dioxide-containing gas are introduced into a recycling apparatus 100. In the recycling apparatus 100, the carbon dioxide in the carbon dioxide-containing gas is used to adjust the PH value of the tetramethyl ammonium carbonate-containing solution. The goal is to lower the PH value of the tetramethyl ammonium carbonate-containing solution to less than 9 before sending it to a waste solution recycle factory. The carbon dioxide-containing gas used in the present invention is industrial waste gas generated during semiconductor manufacturing processes.

Please refer to FIG. 1. The recycling apparatus 100 of the present invention includes a reactor 10. The reactor 10 includes a cover 10a, a side wall 10c, and a bottom 10b. As shown in FIG. 1 and FIG. 3, the reactor 10 is preferably cylindrical in shape. Please continue to refer to FIG. 1, a fluid inlet 12a and a fluid recycle inlet 12b are arranged on the side wall 10c. A fluid supply tube 14 is suspended near the cover 10a inside the reactor 10, and the fluid supply tube 14 connects the fluid inlet 12a and the fluid recycle inlet 12b. Both the fluid inlet 12a and the fluid recycle inlet 12b are used for introducing tetramethyl ammonium carbonate-containing solutions with a PH value greater than or equal to 9. Numerous spray nozzles 16 are arranged on the fluid supply tube 14, with each spray nozzle 16 having an inlet 16a that is connected to the fluid supply tube 14. The outlet 16b of each spray nozzle 16 faces towards the bottom 10b of the reactor 10. The spray nozzle 16 is used to atomize tetramethyl ammonium carbonate-containing solution to form droplets, which are then sprayed toward the bottom 16b. Numerous spray nozzles 18 are installed on the side wall 10c. The nozzles 18 include those with the same distance from the bottom 10b as well as those with different distances from the bottom 10b. For example, the distances respectively between the nozzles 18a/18b/18c and the bottom 10b are distances d1/d2/d3. The distance d1 is greater than the distance d2, and the distance d2 is greater than the distance d3. Furthermore, there are numerous nozzles 18a/18b/18c. In this embodiment, the nozzles 18 with different distances from the bottom 10b can be aligned along the vertical direction Y in the same column. There are three nozzles 18 in the same column. Based on the different embodiments, the number of nozzles 18 in the same column can be increased or decreased. In other cases, the nozzles 18 may also not be arranged in the same column. The nozzles 18 with different distances from the bottom 10b can be disposed in a staggered manner. Additionally, all of the nozzles 18 are used to spray carbon dioxide-containing gas toward the center of the reactor 10. In addition, a storage tank 22 is placed at the bottom 10b of the reactor 10, and a filter 24 is connected to the storage tank 22. The storage tank 24 is used to collect the first treated solution 26 formed after the reaction of the tetramethyl ammonium carbonate-containing solution and the carbon dioxide-containing gas. The filter 24 is used to filter the photoresist in the first treated solution 26. The first treated solution 26 which is filtered becomes the second treated solution 28. Moreover, a three-way valve 32 is connected to the filter 24, a collection tank 34, and the fluid recycle inlet 12b. A PH detector 30 is installed on the three-way valve 32, and the PH detector 30 is used to measure the PH value of the second treated solution 28. The three-way valve 32 can control whether to send the second treated solution 28 to the collection tank 34 or to the fluid recycle inlet 12b.

As shown in FIG. 2, a horizontal direction X parallels the bottom 10b of the reactor 10. A first angle A is disposed between the horizontal direction X and each nozzle 18. The first angle A ranges from 0 to 80 degrees. Each of the nozzles 18 is required to face either the cover 10a of the reactor 10 or be parallel to the horizontal direction X so that the carbon dioxide-containing gas will be sprayed toward the cover 10a of the reactor 10 or toward the side wall 10c of the reactor 10 which is opposite to the position of nozzles 18. Spraying the carbon dioxide-containing gas toward the cover 10a of the reactor 10 can extend the time the carbon dioxide-containing gas stays in the air. Therefore, each of the nozzles 18 must not face the bottom 10b, otherwise the carbon dioxide-containing gas will stay in the air for too short time. Additionally, the first angle A of each of the nozzles 18 will vary based on the distance between the nozzle 18 and the bottom 10b. According to the preferred embodiment of the present invention, the first angle A of the nozzles 18 closer to the bottom 10b of the reactor 10 is larger than the first angle A of the nozzles 18 farther from the bottom 10b, while the first angle of the nozzle 18 closest to the cover 10a of the reactor 10 is preferably 0. In other words, the carbon dioxide-containing gas sprayed from the nozzle 18 closest to the cover 10a of the reactor 10 forms a barrier along the horizontal direction X, preventing the carbon dioxide-containing gas from spraying toward the cover 10a to affect the falling of the tetramethyl ammonium carbonate-containing solution toward the bottom 10b. In the case of the three nozzles 18a/18b/18c in this embodiment, since the distance d3 is smaller than the distance d2, the nozzle 18c is closer to the bottom 10b of the reactor 10 than the nozzle 18b. Since the distance d2 is smaller than the distance d1, the nozzle 18b is closer to the bottom 10b of the reactor 10 than the nozzle 18a. The first angle A of the nozzle 18c which is closer to the bottom 10b of the reactor 10 is larger than the first angle A of the nozzle 18b which is farther from the bottom 10b. The angle A of the nozzle 18a which is closest to the cover 10a of the reactor 10 is 0. Furthermore, the flow rate of the carbon dioxide-containing gas from the nozzle 18 closer to the bottom 10b is greater than the flow rate of the carbon dioxide-containing gas from the nozzle 18 farther from the bottom 10b. Therefore, the flow rate of the carbon dioxide-containing gas from nozzle 18c is greater than the flow rate of the carbon dioxide-containing gas from nozzle 18b. The flow rate of the carbon dioxide-containing gas from nozzle 18b is greater than the flow rate of the carbon dioxide-containing gas from nozzle 18a.

As shown in FIG. 3, according to the first preferred embodiment of the present invention, when viewed from the cover 10a toward the bottom 10b, several nozzles 18 are arranged on the side wall 10c of the reactor 10. The nozzles 18 which are at the same distance from the bottom are evenly distributed on the side wall 10c to surround the side wall 10c. Please refer to both FIG. 2 and FIG. 3. Taking the topmost nozzle 18a as an example, all nozzles 18a with a distance of d1 from the bottom 10b are arranged in an evenly distributed manner along the circumference to surround the side wall 10c, when viewed from the cover 10a toward the bottom 10b. The nozzles 18b/18c are also evenly distributed in the same manner. Furthermore, starting from the side wall 10c and measured in the counterclockwise direction R1, there is a second angle B between the side wall 10c and each of the nozzles 18a. The second angle B ranges from 10 to 80 degrees. In FIG. 3, the second angle B is shown in the same degrees as an example. The nozzles 18b/18c also have the second angles B. In other words, there is a second angle B between the side wall 10c and each of the nozzles 18. The second angle B ranges from 10 to 80 degrees, and the second angle B of each nozzle 18 can be the same or different.

After the carbon dioxide-containing gas is sprayed from each of the nozzles 18, the carbon dioxide-containing gas follows a predetermined path toward the center of the reactor 10, generating a counterclockwise airflow F1 at the center of the reactor 10. Please refer to FIG. 1, FIG. 2, and FIG. 3. Since the nozzles are directed toward the cover 10a or are parallel to the horizontal direction X, the carbon dioxide-containing gas forms a counterclockwise airflow F1 that rises toward the cover 10a. Due to the continuous spraying of the carbon dioxide-containing gas, the gas will rotate for long period at the center of the reactor 10, allowing the carbon dioxide-containing gas to react with the droplets of the tetramethyl ammonium carbonate-containing solution.

According to the second preferred embodiment of the present invention, the carbon dioxide-containing gas can also generate a clockwise airflow F2 at the center of the reactor 10. Please refer to FIG. 1, FIG. 2, and FIG. 4. As shown in FIG. 4, several nozzles 18 can be arranged on the side wall 10c of the reactor 10. The nozzles 18 having the same distance from the bottom 10b are evenly distributed along the circumference to surround the side wall 10c. In FIG. 4, only the topmost nozzle 18a is shown as an example. Viewed from the cover 10a toward the bottom 10b, starting from the side wall 10c and measured in the clockwise direction R2, there is a second angle B between the side wall 10c and each of the nozzles 18a. The second angle B ranges from 10 to 80 degrees, and the second angle B of each nozzle 18a can be the same or different. In FIG. 4, the second angle B is shown in the same degrees. Similarly, there is a second angle B between the side wall 10c and each of the nozzles 18. The second angle B ranges from 10 to 80 degrees, and the second angle B of each nozzle 18 can be the same or different.

After the carbon dioxide-containing gas is sprayed from each of the nozzles 18, the carbon dioxide-containing gas follows a predetermined path toward the center of the reactor 10, generating a clockwise airflow F2 at the center of the reactor 10. Except for the second angle B which is calculated in the clockwise direction R2 differs from FIG. 3 of the first preferred embodiment, the positions, angles, and flow rates of all the nozzles 18 are the same as those in the first preferred embodiment. As shown in FIG. 2, similarly, in the second preferred embodiment, the first angles A of the nozzles 18, such as nozzles 18a/18b/18c, respectively ranges from 0 to 80 degrees, and the nozzles 18 are directed either toward the cover 10a or parallel to the horizontal direction X. The first angle A of the nozzle 18 closer to the bottom 10b of the reactor 10 is larger than the first angle A of the nozzle 18 farther from the bottom 10b. The first angle A of the nozzle 18 closest to the cover 10a of the reactor 10 is preferably 0. Furthermore, the flow rate of the carbon dioxide-containing gas from the nozzle 18 closer to the bottom 10b is greater than the flow rate of the carbon dioxide-containing gas from the nozzle 18 farther from the bottom 10b. In this way, the carbon dioxide-containing gas forms a clockwise airflow F2 that rises toward the cover 10a.

As shown in FIG. 1 and FIG. 5, after forming the tetramethyl ammonium carbonate-containing solution, a process for recycling the tetramethyl ammonium carbonate-containing solution is carried out using a recycling device 100. The process for recycling the tetramethyl ammonium carbonate-containing solution includes feeding the tetramethyl ammonium carbonate-containing solution and the carbon dioxide-containing gas into the reactor 10 of the recycling device 100. As shown in FIG. 1, the tetramethyl ammonium carbonate-containing solution flows into the fluid supply tube 14 through the fluid inlet 12a, and then is atomized by multiple spray nozzles 16 before being sprayed toward the bottom 10b of the reactor 10. The atomized tetramethyl ammonium carbonate-containing solution preferably forms droplets with a diameter ranging from 10 to 1000 micrometers. At the same time, the carbon dioxide-containing gas is turned on and sprayed from the nozzles 18. Depending on whether the reactor 10 is in the first preferred embodiment (FIG. 3) or the second preferred embodiment (FIG. 4), the carbon dioxide-containing gas will form a counterclockwise airflow F1 or a clockwise airflow F2 rising toward the cover 10a. In this way, the carbon dioxide-containing gas reacts with the droplets of the tetramethyl ammonium carbonate-containing solution, causing the PH value of the tetramethyl ammonium carbonate-containing solution to decrease due to the adjustment by the carbon dioxide-containing gas.

When the tetramethyl ammonium carbonate-containing solution reacts with the carbon dioxide-containing gas, the tetramethyl ammonium carbonate-containing solution forms the first treated solution 26. The first treated solution 26 then falls into the storage tank 22. After the first treated solution 26 accumulates to a predetermined volume or weight, the supply of the tetramethyl ammonium carbonate-containing solution to the fluid supply tube 14 is stopped, and the carbon dioxide-containing gas is turned off. Later, the first treated solution 26 is transported to the filter 24 to filter out the photoresist to form a second treated solution 28. Subsequently, the second treated solution 28 is sent to the PH detector 30 to measure the PH value of the second treated solution 28. If the PH value of the second treated solution 28 is greater than or equal to 9, the second treated solution 28 is reintroduced into the fluid supply tube 14 through the fluid recycle inlet 12b, restarting the process of recycling the tetramethyl ammonium carbonate-containing solution. The carbon dioxide-containing gas is then turned on to mix with the second treated solution 28 to further reduce the PH value of the second treated solution 28. If the PH value of the second treated solution 28 is less than 9, the second treated solution 28 is sent to the collection tank 34. Once the second treated solution 28 in the collection tank 34 accumulates to a predetermined volume or weight, it is sent to a waste solution recycle factory. Furthermore, an untreated tetramethyl ammonium carbonate-containing solution is fed into the fluid supply tube 14 from the fluid inlet 12a, and turning on the carbon dioxide-containing gas to restart another process for recycling the tetramethyl ammonium carbonate-containing solution. Thus, the method of carbon capture and recycling the tetramethyl ammonium carbonate-containing solution of the present invention is completed

The present invention has the following features, but is not limited to these. First, carbon dioxide collected from industrial waste gas is sprayed through nozzles. Secondly, the angle and direction of the nozzles are intentionally adjusted. Thirdly, the flow rate of the carbon dioxide-containing gas sprayed from nozzles at different heights are controlled in a specific rate. These features cause the carbon dioxide-containing gas to form a clockwise or counterclockwise airflow that rises toward the cover at the center of the reactor. As a result, the carbon dioxide-containing gas stays in the air for an extended period, increasing the reaction time with the droplets of the tetramethyl ammonium carbonate-containing solution. This allows for carbon capture and efficient reduction of the PH value of the tetramethyl ammonium carbonate-containing solution at the same time.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of carbon capture and recycling tetramethyl ammonium carbonate-containing solution, comprising:
providing a recycling apparatus, wherein the recycling apparatus comprises:
a reactor comprising a cover, a side wall and a bottom, wherein a fluid inlet and a fluid recycle inlet are arranged on the side wall;
a fluid supply tube suspended in the reactor close to the cover, and the fluid supply tube connected to the fluid inlet and the fluid recycle inlet;
a plurality of spray nozzles disposed on the fluid supply tube, wherein an inlet of each of the plurality of spray nozzles is connected to the fluid supply tube, and an outlet of each of the plurality of spray nozzles faces the bottom of the reactor; and
a plurality of nozzles arranged on the side wall, wherein some of the plurality of nozzles are arranged at a same distance from the bottom, while others of the plurality of nozzles are arranged at different distances from the bottom, the some of the plurality of nozzles which are at the same distance from the bottom are evenly distributed on the side wall to surround the side wall;
a process of recycling tetramethyl ammonium carbonate-containing solution being performed by using the recycling apparatus, wherein the process comprises:
supplying a tetramethyl ammonium carbonate-containing solution into the fluid supply tube and spraying the tetramethyl ammonium carbonate-containing solution out from the spraying nozzles; and
turning on a carbon dioxide-containing gas to spray the carbon dioxide-containing gas from each of the plurality of nozzles, wherein a PH value of the tetramethyl ammonium carbonate-containing solution is reduced after adjusted by the carbon dioxide-containing gas.

2. The method of carbon capture and recycling tetramethyl ammonium carbonate-containing solution of claim 1, wherein a horizontal direction is parallel to the bottom of the reactor, a first angle is disposed the horizontal direction and each of the plurality of nozzles, the first angle is between 0 and 80 degrees, and each of the plurality of nozzles faces the cover or is parallel to the horizontal direction.

3. The method of carbon capture and recycling tetramethyl ammonium carbonate-containing solution of claim 2, wherein a vertical direction is perpendicular to the bottom of the reactor, a group of the plurality of nozzles are arranged in a column along the vertical direction, along the column, the nozzle which is closer to the bottom has the first angle which is larger than the first angle of the nozzle which is farther from the bottom.

4. The method of carbon capture and recycling tetramethyl ammonium carbonate-containing solution of claim 2, wherein the nozzle which is closer to the bottom has the first angle which is larger than the first angle of the nozzle which is farther from the bottom.

5. The method of carbon capture and recycling tetramethyl ammonium carbonate-containing solution of claim 2, wherein a flow rate of the carbon dioxide-containing gas from the nozzle which is closer to the bottom is greater than a flow rate of the carbon dioxide-containing gas from the nozzle which is farther from the bottom.

6. The method of carbon capture and recycling tetramethyl ammonium carbonate-containing solution of claim 2, wherein as viewed from the cover towards the bottom, starting from the side wall and measuring in a counterclockwise direction, a second angle is disposed between the side wall and each of the plurality of nozzles, the second angle is between 10 to 80 degrees, after the carbon dioxide-containing gas is sprayed out from each of the plurality nozzles, the carbon dioxide-containing gas follows a predetermined path towards a center of the reactor, generating a counterclockwise airflow at the center of the reactor.

7. The method of carbon capture and recycling tetramethyl ammonium carbonate-containing solution of claim 2, wherein as viewed from the cover towards the bottom, starting from the side wall and measuring in a clockwise direction, a second angle is disposed between the side wall and each of the plurality of nozzles, the second angle is between 10 to 80 degrees, after the carbon dioxide-containing gas is sprayed out from each of the plurality nozzles, the carbon dioxide-containing gas follows a predetermined path towards a center of the reactor, generating a clockwise airflow at the center of the reactor.

8. The method of carbon capture and recycling tetramethyl ammonium carbonate-containing solution of claim 1, wherein the recycling apparatus further comprises:
a storage tank located at the bottom of the reactor; and
a filter connected to the storage tank.

9. The method of carbon capture and recycling tetramethyl ammonium carbonate-containing solution of claim 8, wherein the process of recycling tetramethyl ammonium carbonate-containing solution further comprises:
forming a first treated solution by reacting the tetramethyl ammonium carbonate-containing solution sprayed from the plurality of spray nozzles and the carbon dioxide-containing gas sprayed from the plurality of nozzles at the center of the reactor, and the first treated solution being collected to the storage tank;
stopping inputting the tetramethyl ammonium carbonate-containing solution into the fluid supply tube, and turning off the carbon dioxide-containing gas; and
forming a second treated solution by transferring the first treated solution from the storage tank to the filter to remove the photoresist.

10. The method of carbon capture and recycling tetramethyl ammonium carbonate-containing solution of claim 9, wherein the process of recycling tetramethyl ammonium carbonate-containing solution further comprises:
testing the PH value of the second treated solution, if the PH value is greater than or equal to 9, inputting the second treated solution into the fluid supply tube from the fluid recycle inlet, and turning on the carbon dioxide-containing gas to mix the carbon dioxide-containing gas with the second treated solution to lower the PH value of the second treated solution.

11. The method of carbon capture and recycling tetramethyl ammonium carbonate-containing solution of claim 10, wherein the process of recycling tetramethyl ammonium carbonate-containing solution further comprises:
testing the PH value of the second treated solution, if the PH value is less than 9, transferring the second treated solution to a collection tank.

12. The method of carbon capture and recycling tetramethyl ammonium carbonate-containing solution of claim 11, wherein the process of recycling tetramethyl ammonium carbonate-containing solution further comprises:
after transferring the second treated solution to the collection tank, inputting an untreated tetramethyl ammonium carbonate-containing solution into the fluid supply tube from the fluid inlet, and turning on the carbon dioxide-containing gas.

13. The method of carbon capture and recycling tetramethyl ammonium carbonate-containing solution of claim 1, further comprising:
before performing the process of recycling tetramethyl ammonium carbonate-containing solution, providing a tetramethyl ammonium carbonate-containing waste solution, and heating the tetramethyl ammonium carbonate-containing waste solution to increase a concentration of tetramethyl ammonium carbonate in the tetramethyl ammonium carbonate-containing waste solution to 10-30% (weight/weight percentage) to form the tetramethyl ammonium carbonate-containing solution.
